(19) United States
(12) Patent Application Publication
(10) Pub. No.: US 2008/0090988 A1
(43) Pub. Date: Apr. 17, 2008

(54) Method for handling polysilazane or polysilazane solution, polysilazane or polysilazane solution, and method for producing semiconductor device

(76) Inventors: Keisuke Nakazawa, Yokohama-shi (JP); Katsuhiko Tachibana, Yokohama-shi (JP); Takeshi Hoshi, Yokohama-shi (JP); Masahiro Kiyotoshi, Sagamihara-shi (JP); Atsuko Kawasaki, Yokohama-shi (JP); Osamu Arisumi, Kuwana-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/905,049

(22) Filed: Sep. 27, 2007

(30) Foreign Application Priority Data
Sep. 29, 2006 (JP) 2006-268073

(51) Int. Cl. C08G 77/12; H01L 21/31

(52) U.S. Cl. 528/31; 438/778; 257/E21.266

(57) ABSTRACT

A method for handling polysilazane or a polysilazane solution includes synthesizing polysilazane and preparing the polysilazane solution in a first space isolated from outside air. The first space is mainly supplied with air from which amine, basic substance, volatile organic compound and acidic substance are eliminated.

### CROSS-REFERENCE TO RELATED APPLICATIONS

This application is based upon and claims the benefit of priority from prior Japanese Patent Application No. 2006-268073, filed Sep. 29, 2006, the entire contents of which are incorporated herein by reference.

### BACKGROUND OF THE INVENTION

1. Field of the Invention

The present invention relates to a method for handling polysilazane or a polysilazane solution that is used for production of semiconductor devices, polysilazane or a polysilazane solution, and a method for producing a semiconductor device.

2. Description of the Related Art

Insulation film materials filled in narrow gaps have been desired in accordance with miniaturization of semiconductor devices. The insulation film used for the semiconductor device is formed, for example, by a CVD (chemical vapor deposition) method or coating method. However, most of these methods cannot completely fill narrow gaps, and large voids are often formed.

However, a silica-base insulation film may be formed in narrow gaps by using a perhydropolysilazane (PHPS) solution as a polysilazane-base material. Polysilazane is also referred to as a silazane-type polymer that is a polymer material having a —(SiH₂—NH)— group as an elementary unit, and is used by being dissolved in a solvent such as xylene and di-n-butylether. Substances in which hydrogen atoms of PHPS are substituted with other functional groups such as methoxy groups have been also widely used in the production of the semiconductor device as members of polysilazane. Perhydropolysilazane is polysilazane having no functional groups and modification groups.

PHPS may be filled in nm-order gaps by rotary coating. In addition, PHPS generates ammonia by reacting with water, and silicon is converted into silicon dioxide by being oxidized in the solution. Accordingly, the silica-base insulation film may be formed even in narrow gaps by heat-treating the coated PHPS film in water vapor. Examples of representative applications include STI (shallow trench isolation), PMD (pre-metal dielectric) and IMD (inter-metal dielectric) disclosed in Jpn. Pat. Appln. KOKAI Publication No. 2004-179614.

Specifically, the silica-base insulation film is formed by the following steps. In a first step, the PHPS solution is spin-coated on a wafer with a rotary applicator at a rotation speed from 1,000 to 4,000 rpm. Then, the wafer is baked in air at about 150° C. to permit the solvent to evaporate in order to obtain a film with a given thickness. Subsequently, the wafer is fired at a temperature from about 230 to about 900° C. in water vapor. Such treatment permits N in PHPS to be substituted with O, and a silicon dioxide film may be formed in fine spaces with a gap distance of 50 nm or less.

Since suppression of leak current from wiring lines is necessary for miniaturization and integration of the semiconductor device, a lower dielectric constant (low-k) material capable of insulating between multilayer wiring lines is desired. Polysilazane obtained by chemical modification of PHPS may be used as the low-k material. Chemical modification of PHPS is achieved by substitution of hydrogen atoms with organic substituents. Fine pores can be efficiently formed after forming the film by selecting a bulky group as the substituent, and the low-k film having good characteristics can be formed.

The method for forming the low-k film using polysilazane is almost the same as the method for forming the PHPS film. Specifically, a polysilazane solution is spin-coated on a substrate with a rotary applicator. The substrate is then baked, and is fired in an atmosphere containing oxygen and water vapor.

The methods for synthesizing polysilazane and chemically modified polysilazane are described in Jpn. Pat. Appln. KOKOKU Publication No. 63-16325 and Japanese Patent No. 3483500. However, details of functions of minute components contained in the thus prepared polysilazane and polysilazane solutions have not been elucidated yet. Minute components (impurities) that are naturally different from the object of the synthesis may be contained in the solvent and catalyst used for the synthesis of polysilazane, or the impurities may be unintentionally mingled during synthesis. Since various chemical substances are present in the air, these substances may be dissolved in polysilazane or in the polysilazane solution while polysilazane or the polysilazane solution is prepared. Trace amount of impurity components mingled and dissolved in the solution may be considered to impose various chemical actions on polysilazane depending on chemical species of the impurities, and properties of the silica-base insulation film and low-k film are largely affected by the impurities.

### BRIEF SUMMARY OF THE INVENTION

According to one aspect of the present invention, there is provided a method for handling polysilazane or a polysilazane solution comprising: synthesizing polysilazane and preparing the polysilazane solution in a first space isolated from outside air, the first space being mainly supplied with air from which amine, basic substance, volatile organic compound and acidic substance are eliminated.

According to one aspect of the present invention, there is provided a polysilazane solution comprising: an amine having an N—R(—R′)(—R″) bond or a basic substance except ammonia in a proportion of 10 ppm or less in a solution of a polymer having a Si—N bond relative to a weight of the polymer, or in a proportion of 10 ppm or less in a side chain, functional group or chemical modification group of a polymer having a Si—N bond relative to a weight of a polysilazane base polymer.

According to one aspect of the present invention, there is provided Polysilazane or a polysilazane solution, wherein a total number of hydrogen in an N—CH_{Z} bond (N is not an atom in a polysilazane base polymer, and z is an integer from 1 to 3) contained in the polysilazane or in the polysilazane solution is 1×10⁻⁵ or less of a sum of the total number of hydrogen in SiA_{X} (A represents hydrogen or a substituent substituting hydrogen, and x is an integer from 1 to 3) and NB_{y} (N is an atom in the polysilazane base polymer, B represents hydrogen or a substituent substituting hydrogen (including the same substituent as A), and y is an integer of 1 or 2) and the number of substituents substituted with hydrogen.

### BRIEF DESCRIPTION OF THE SEVERAL VIEWS OF THE DRAWING

FIG. 1 is a graph showing dependency of the contraction rate of the film obtained in Example 1 on amine concentration;

FIG. 2 is a graph showing the relation between additives and film contraction rate obtained in Example 3;

FIG. 3 shows VOC concentrations in each environment;

FIG. 4 is a graph showing dependency on amine concentration obtained in Example 4;

FIG. 5 is a graph showing dependency of refractive index of the film obtained in Example 5 on amine concentration;

FIG. 6 is a graph showing dependency of the stress of the film obtained in Example 6 on amine concentration;

FIG. 7 is a graph showing dependency of the etching rate of the film obtained in Example 7 on the in-plane position of the wafer;

FIG. 8 is a graph showing dependency of the etching rate of the film obtained in Example 7 on the in-plane position of the wafer;

FIG. 9 shows the presence or absence of peeling of the film obtained in Example 8;

FIG. 10 illustrates a system for forming a clean environment according to Example 10;

FIG. 11 shows the concentrations of chemical substances in the clean room 1 obtained in Example 10;

FIG. 12 illustrates a treatment apparatus according to Example 11;

FIG. 13 illustrates a treatment apparatus according to Example 12;

FIG. 14 shows a flow chart of the production process of usual semiconductor devices; and

FIG. 15 illustrates a film-forming process.

### DETAILED DESCRIPTION OF THE INVENTION

Embodiments of the invention will be described below with reference to the drawings. The constituting elements having approximately the same functions and constitutions are given the same reference numerals, and duplicated explanations thereof are made only when necessary.

(Evaluation of Impurities)

The inventors of the invention have carried out various investigations on the effect of the components mingled in the polysilazane solution and the environment for forming the polysilazane film.

### Example 1

Example 1 relates to the film contraction rate of the silica-base insulation film formed from polysilazane depending on the kind and concentration of impurities in the polysilazane solution.

A sample was prepared by using a solution of perhydropolysilazane (PHPS) as polysilazane manufactured by AZ Electronic Materials. Di-n-butylether was used as the solvent of this solution, which had a concentration of solid fractions of polysilazane of 19.2 wt % (% by weight).

A sample solution was prepared by adding up to 1,000 ppm of 6-dimethylamino-1-hexanol ((CH₃)₂NC₆H₁₂OH) or 2-dimethylamino-1-ethanol ((CH₃)₂NC₂H₄OH) as impurities relative to the weight of polysilazane in the polysilazane solution prepared above.

This sample solution was spin-coated on a silicon wafer at a rotation speed of 826 ppm, and then the solvent was evaporated by baking the wafer at 150° C. for 3 minutes. The thickness of the polysilazane film was about 650 nm after baking. The wafer was fired in a water vapor atmosphere at 400° C. for 15 minutes using a vertical heating furnace.

Polysilazane is not completely converted into a silicon dioxide film in the production process of the semiconductor device. In other words, the proportion of conversion of the polysilazane film into the silicon dioxide film is different depending on the position used in the semiconductor device. For example, a polysilazane film (silicon dioxide film) having desired characteristics regarding etching rate by RIE (reactive ion etching) can be formed by appropriately controlling the proportion of conversion of the polysilazane film into the silicon dioxide film. Accordingly, it is necessary to control the proportion of conversion of the polysilazane film, which is formed from the polysilazane solution, into the silicon dioxide film with a certain extent of accuracy.

A contraction rate of the polysilazane film was observed in Example 1 as one of the indices of changes of the characteristics of the polysilazane film depending on the proportion of conversion of the polysilazane film into the silicon dioxide film.

FIG. 1 shows dependency of the contraction rate of the film obtained in Example 1 of the invention on amine concentration. The contraction rate of the film was calculated from the thickness of the polysilazane film before and after firing. As shown in FIG. 1, the contraction rate of the film is not changed by increasing the amount of addition of 2-dimethylamino-1-ethanol. On the contrary, the contraction rate of the film increases with the increase in the amount of addition of 6-dimethylamino-1-hexanol. Basic substances (amines) having such amino groups have been known to serve as catalysts for facilitating conversion of polysilazane into silicon dioxide. Therefore, the fact that the contraction rate of the film increases by adding 6-dimethylamino-1-hexanol suggests that the conversion into silicon dioxide is facilitated by the catalytic action of the amine.

The extent of contraction rate of the film can also be detected by observing the surface of the wafer after firing. The surface of the wafer is roughened as the contraction rate of the film increases, and morphology of the surface is impaired.

Thus, it was found that the contraction rate of the polysilazane film largely changes by the change of the amine concentration depending on the kind of the mingled amines. Accordingly, a polysilazane film having a desired degree of conversion into silicon dioxide may be hardly formed depending on the kind of the amine. In another experiment, the order of the catalytic activity of dimethylamino alcohol was calculated from the contraction rate of the film as follows:
6-dimethylamino-1-hexanol (C6)=4-dimethylamino-1-butanol (C4)>2-dimethylamino-1-ethanol (C2)

### Example 2

Substances other than amine were used as impurities added to the polysilazane solution in Example 2.

A sample solution was prepared by adding from 10 to 1,000 ppm of propyleneglycol monomethylether acetate (PGMEA) relative to the concentration of solid fractions to the polysilazane solution as used in Example 1. It was confirmed by ¹H-NMR (nuclear magnetic resonance) that PGMEA forms Si—O—CH₂ bonds by reacting with the solute.

This sample solution was applied on the wafer by the same method and under the same condition as in Example 1, and a polysilazane film containing silicon dioxide was formed on the wafer after baking. Then, the contraction rate of the polysilazane film thus formed was measured by the same method as in Example 1. It was confirmed from the results that the contraction ratio was not changed by adding PGMEA and irrespective of the amount of addition of PGMEA. The results showed that, while PGMEA reacts with polysilazane, it does not affect on the oxidation reaction by firing, i.e. on conversion of polysilazane into silicon dioxide.

### Example 3

Amines and other substances were added in Example 3.

Prior to the examples of adding the amine and other substances, an example of adding only a substance that is to be used together with the amine will be described. Examples of the additive used were alcohols and acidic catalysts. The contraction rate of the film was investigated by using samples containing these additives by the same method as in Example 2, and it was confirmed that the results are the same as those obtained when no additives were used. While examples using the amine as well as PGMEA are shown in Example 3, the result obtained when PGMEA was added alone was the same as that obtained when PGMEA was not added as shown in Example 2.

Subsequently, a sample solution was prepared by adding 10 ppm of 6-dimethylamino-1-hexanol relative to the weight of polysilazane to the polysilazane solution as in Example 1. An alcohol, an acidic catalyst or PGMEA was added in a proportion of 100 ppm, respectively, in addition to the amine. Sample solutions as described below were thus obtained:

1. Sample solution containing no impurities;

2. Sample solution containing amine;

3. Sample solution containing amine and alcohol;

4. Sample solution containing amine and acidic catalyst; and

5. Sample solution containing amine+PGMEA

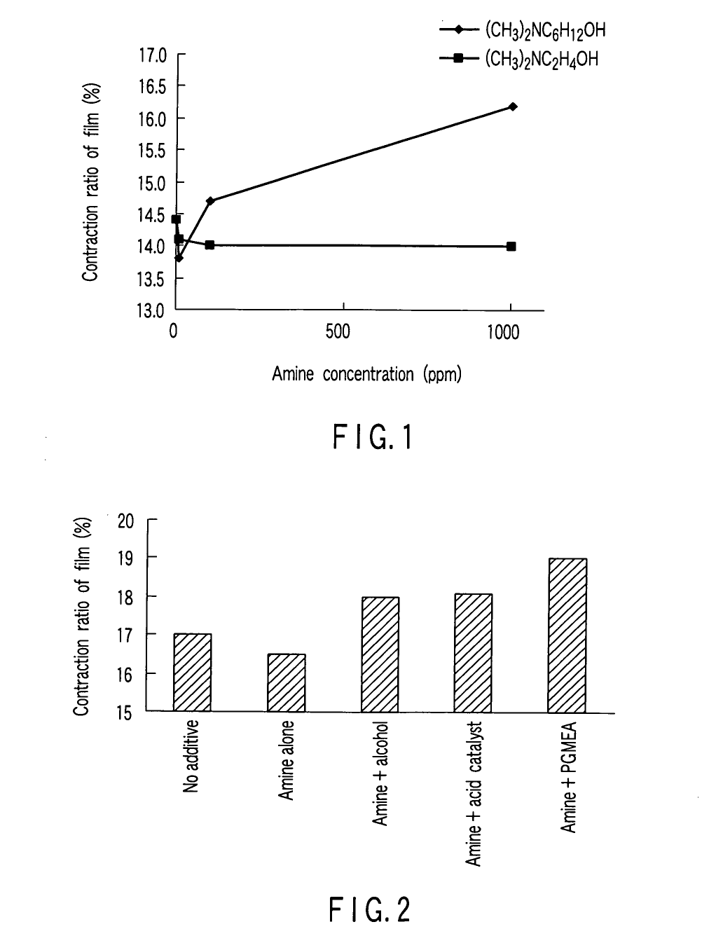

Then, each sample solution was applied on the wafer under the same condition and by the same method as in Example 1, and a polysilazane film containing silicon dioxide was formed on the wafer by baking. Then, the contraction rate of each polysilazane film thus obtained was measured. The results are shown in FIG. 2. FIG. 2 shows the relation between the additive and contraction ratio of the film obtained in Example 3 of the invention.

As shown in FIG. 2, the contraction rate is about 17% when the amine is added alone or not added, and the difference in the contraction ratio between the two cases is not so large. However, the contraction ratio of the film increases when another substance is added in addition to the amine. It is shown that the contraction ratio of the film largely increases when the amine and PGMEA are added as compared with the film formed by adding no additives.

As shown above, the contraction rate of the film when either an alcohol, an acidic catalyst or PGMEA is added alone is the same as the contraction rate of the film when no additives are added. On the contrary, FIG. 2 shows that the contraction rate of the film increases by adding an amine in addition to the above-mentioned additive as compared with the contraction rate when no additives are added. The result suggests that adding the amine and other substances together causes a synergic effect on conversion of polysilazane into silicon dioxide. In other words, a substance that causes no changes on the contraction rate of the film as long as the substance is added alone, may affect the contraction rate of the film by adding the amine and the substance together. Accordingly, it was found desirable not to add amine in terms of possibility that other substances may be added to the polysilazane solution.

### Example 4

The effects of addition of the amine and the environment for handling the polysilazane solution on the polysilazane film were investigated in Example 4 in terms of the contraction rate of the polysilazane film.

Sample solutions were prepared by adding respective amounts of 6-dimethylamino-1-hexanol up to 50 ppm to the polysilazane solution as in Example 1. The solutions were prepared in two conditions, i.e. in an environment (clean environment) containing a low concentration of a volatile organic compound (VOC) and in an environment (contaminated environment) containing a high concentration of VOC.

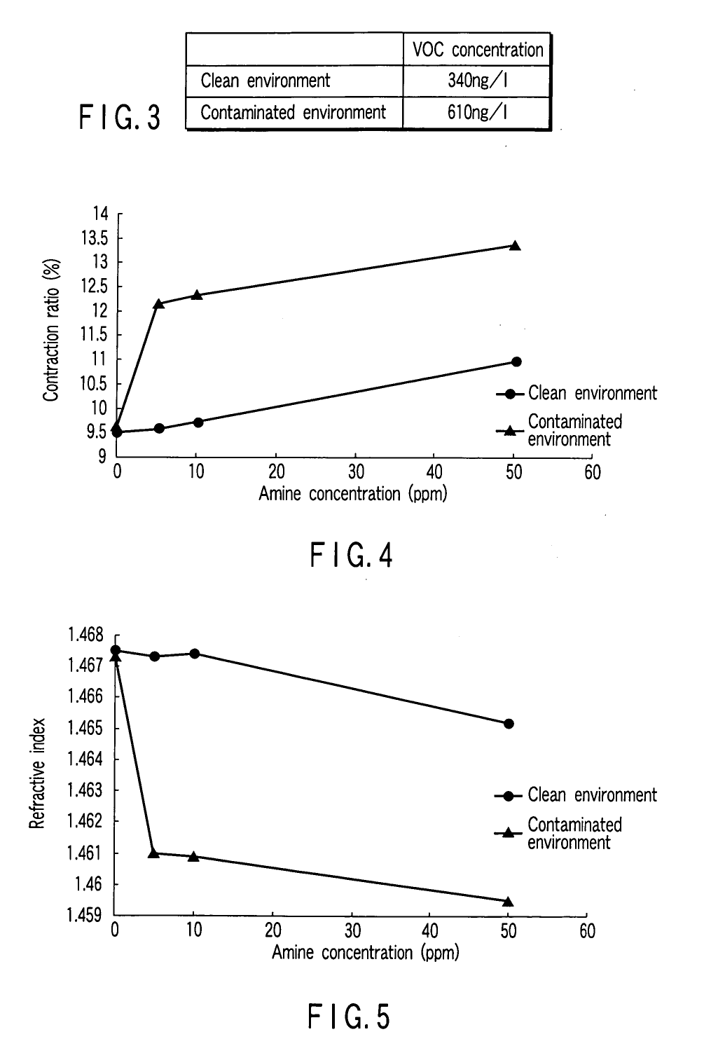

FIG. 3 shows representative VOC concentrations (reduced to hexadecane including butylether as the solvent) in the both environments. FIG. 3 shows examples of the VOC concentration in the respective environments. Esters, ketones and alcohols that are liable to react with polysilazane were contained in the contaminated environment. VOC has high volatility and is readily dissolved in the liquid. Xylene and butylether as solvents of polysilazane are able to dissolve most of the above-mentioned esters, ketones and alcohols.

The sample solution was spin-coated on a silicone wafer at a rotation speed of 826 rpm, and the solvent was evaporated by baking at 150° C. for 3 minutes. The thickness of the polysilazane film was about 650 nm after baking. The wafer was fired at 300° C. for 30 minutes in a water vapor atmosphere using a vertical heating furnace.

FIG. 4 shows the contraction rates of the thickness of the film before and after firing. FIG. 4 shows dependency of the contraction rate of the film on amine concentration in each environment obtained in Example 4 of the invention. As shown in FIG. 4, the contraction rate of the sample prepared in the clean environment increases, with a gradient that may be considered to be constant, in the region of the amine concentration up to 10 ppm. The contraction rate slowly increases with the increase in the amine concentration in the region of the amine concentration exceeding 10 ppm.

When the sample is prepared in a contaminated environment, on the other hand, the contraction rate leaps by adding 5 ppm of the amine, and the contraction rate gradually increases in the concentration region exceeding 5 ppm with approximately the same gradient as that in the clean environment. The reason why the contraction rate leaps even by adding 5 ppm of the amine in the contaminated environment may be elucidated by the mechanism shown in Example 3. That is, a catalytic function of a minute amount of substances contained in the contaminated environment is expressed by a synergic effect with the amine, and conversion of polysilazane into silicon dioxide is advanced.

The result of evaluation described above is an example of evaluation of the environment when the polysilazane solution is prepared. However, the same holds true for any environments for handling polysilazane-base substances such as synthesis and chemical modification of polysilazane, filling of the polysilazane solution into a vessel, transfer of the polysilazane solution from one vessel to another vessel, hermetic sealing of the polysilazane solution and film forming step using the polysilazane solution.

The phrase “handling” of the polysilazane solution used throughout the specification and claims of the invention includes all the works concerning polysilazane and polysilazane solution such as synthesis and chemical modification of polysilazane, filling of the polysilazane or polysilazane solution into a vessel, transfer of the polysilazane solution from one vessel to another vessel, hermetic sealing of the polysilazane solution and film forming step using the polysilazane solution.

The results of this example show that the substances contained in the contaminated environment affect conversion of polysilazane into silicon dioxide when an amine is mingled in the solution. It was shown that not only impurities in the polysilazane solution but also the environments for handling the polysilazane solution are important. Accordingly, the lower the concentration of VOC is, the better, in the environment for handling the polysilazane solution.

When the polysilazane solution is prepared in a contaminated environment and amine is mingled in the solution even in a trace amount, in particular, the rate of change of the contraction rate of the polysilazane film from the contraction rate when no amine is added becomes quite large. Accordingly, the lower the amine concentration is, the better. In the case where the polysilazane solution is prepared in a clean environment, on the other hand, the contraction rate of the polysilazane film is approximately constant when the concentration of the amine, which is reduced to the concentration of 6-dimethylamino-1-hexanol, contained in the polysilazane solution is 10 ppm or less per solid fraction of polysilazane. Accordingly, the amine concentration is desirably 10 ppm or less.

### Example 5

The effects of addition of the amine and handling environment of the polysilazane solution on the polysilazane film were investigated in Example 5 in terms of the refractive index of the polysilazane film.

The refractive index of the polysilazane film was measured in Example 5 using the polysilazane film after firing in Example 4 as a sample. The results are shown in FIG. 5. FIG. 5 shows dependency of the refractive index of the film on amine concentration in each environment obtained in Example 5. The VOC concentration in each environment is the same as in Example 4.

As shown in FIG. 5, few changes of the refractive index were observed up to the concentration of 6-dimethylamino-1-hexanol of 10 ppm when the solution was prepared in the clean environment as in the tendency of the changes of the contraction rate (see FIG. 4). The refractive index slightly decreases when the concentration exceeds 10 ppm. This suggests that conversion of polysilazane into silicon dioxide has advanced.

Advance of oxidation was suggested as the change of the contraction rate when the solution was prepared in the contaminated environment. The refractive index is remarkably decreased up to the amount of the amine of 5 ppm in the contaminated environment, and slowly decreases with almost the same gradient as the gradient in the clean environment when the amount of the amine exceeds 5 ppm. Since the refractive index vigorously changes in the contaminated environment even at the concentration of the amine of 5 ppm or less, it was shown that the solution is preferably prepared in the clean environment.

The above-mentioned results of evaluation show an example of evaluation of the environment for preparing the polysilazane solution. However, the same holds true for any environments for handling polysilazane-base substances such as synthesis and chemical modification of polysilazane, filling of the polysilazane solution into a vessel, transfer of the solution from one vessel to another vessel and film-forming steps using the polysilazane solution.

The results of this example suggest the effect of the substance contained in the contaminated environment on conversion of polysilazane into silicon dioxide when an amine is mingled. This means that not only impurities in the polysilazane solution but also the environments for handling the polysilazane solution are important. Generally, the lower the VOC concentration is, the better, in the handling environment. In the case where the polysilazane solution was prepared in the contaminated environment, in particular, the rate of change of the refractive index of the polysilazane film from the refractive index when no amine is added is very large even when a trace amount of the amine is mingled. Accordingly, the lower the amine concentration is, the better. In the case where the solution is prepared in the clean environment, on the other hand, the refractive index of the polysilazane film is almost constant when the amine concentration, which is reduced to the concentration of 6-dimethylamino-1-hexanol, contained in the polysilazane solution is 10 ppm or less per solid fraction of polysilazane. Accordingly, the amine concentration is desirably 10 ppm or less.

### Example 6

The effects of addition of the amine and the environment for handling the polysilazane solution on the polysilazane film were investigated in Example 6 in terms of stress of the polysilazane film.

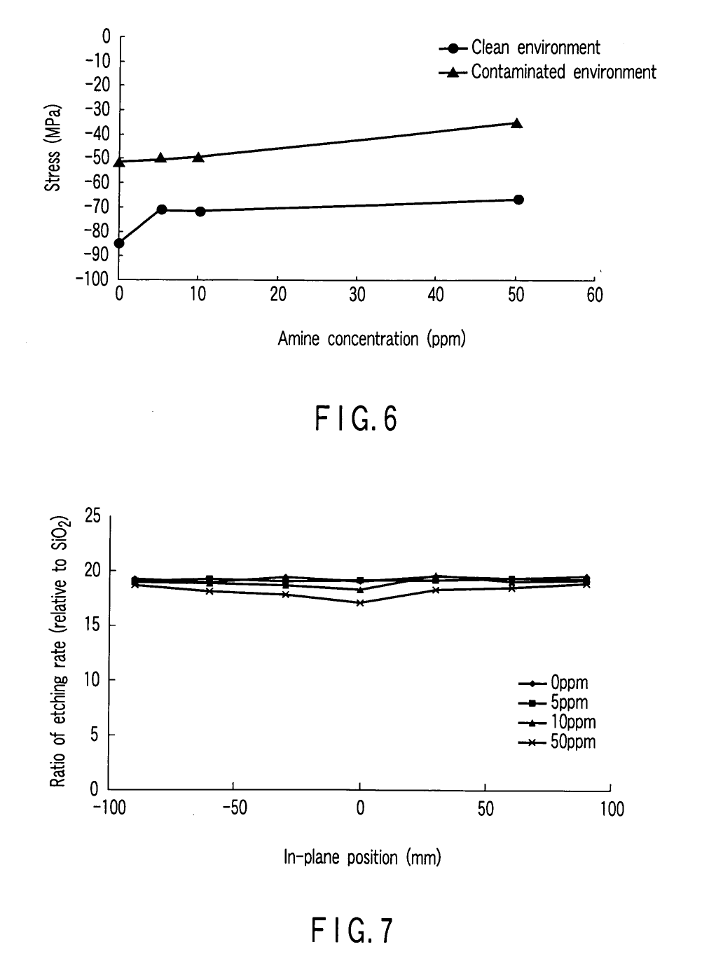

The stress of the polysilazane film was measured in Example 6 using the polysilazane film after firing in Example 4 as the sample. The results are shown in FIG. 6. FIG. 6 shows dependency of the stress of the film after firing on amine concentration in each environment obtained in Example 6. The concentration of VOC in each environment is the same as in Example 4.

In FIG. 6, tensile stress of the polysilazane film formed on the substrate is defined as a positive stress, while contraction stress of the polysilazane film on the substrate is defined as a negative stress. Accordingly, the stress that is larger in the negative direction, or the larger absolute value of the stress in the range of negative stress, refers to higher contraction stress on the substrate. This means that the polysilazane film is hardly peeled.

As shown in FIG. 6, the tensile stress is always smaller in the contaminated environment than in the clean environment, and the tensile stress decreases in accordance with the increase in the amine concentration. It is to be noted that the tensile stress of the film in which 50 ppm of the amine is mingled during preparation of the sample in the clean environment is not higher than the tensile stress of the film prepared in the contaminated environment with no mingling of the amine. The difference in the stress between the contaminated environment and the clean environment at an amine concentration of 0 ppm suggests that VOCs (esters, ketones and alcohols) detected by gas phase analysis are spontaneously mingled into the polysilazane solution, and the stress is directly affected by the VOCs. This means that it is more effective to handle the solution in the clean environment than suppressing the amine concentration low in the contaminated environment, in terms of the tensile stress of the polysilazane film. In other words, lowering the VOC concentration permits the tensile stress to be reduced and prevents the film from being peeled.

The above-mentioned results of evaluation show an example of evaluation of the environment for preparing the polysilazane solution. However, the same holds true for any environments for handling polysilazane-base substances such as synthesis and chemical modification of polysilazane, filling of the polysilazane solution into a vessel, transfer of the solution from one vessel to another vessel and film-forming steps using the polysilazane solution.

The results in this example show that the handling environment of the polysilazane solution is also important. The lower the VOC concentration is, the better, in the handling environment, and it is desirable that the environment contains no VOC at all.

### Example 7

The polysilazane film was investigated in Example 7 using the ratio of the etching rate of the polysilazane film to the etching rate of the silicon dioxide film.

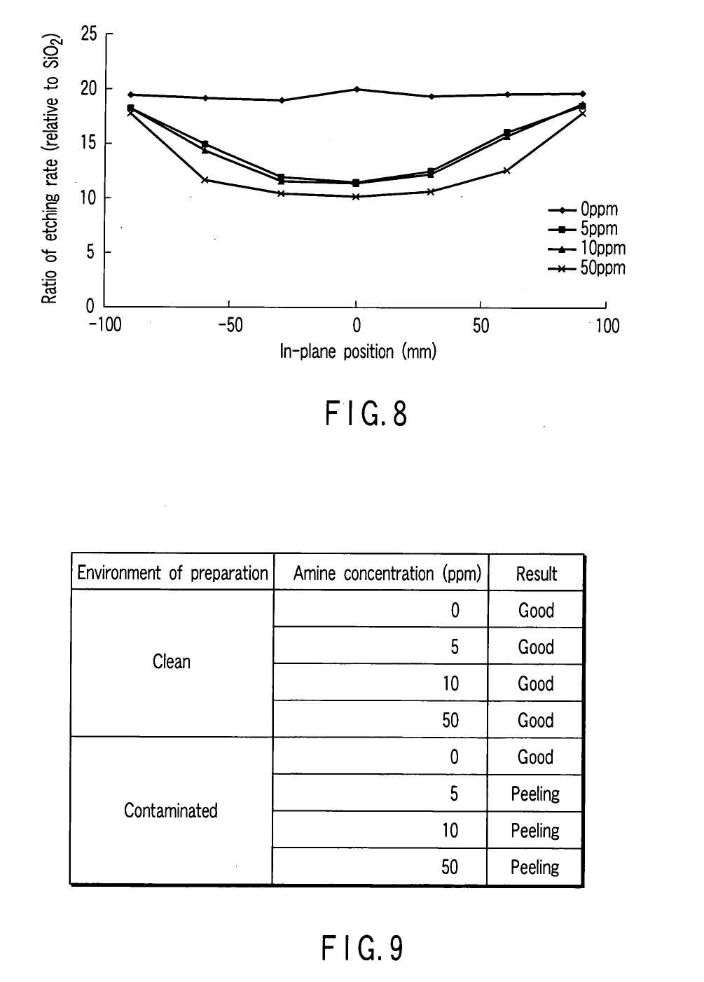

The polysilazane film containing silicon dioxide was dissolved with hydrofluoric acid in Example 7 using the polysilazane film after firing in Example 4 as a sample, and the ratio of the etching rate of the polysilazane film to the etching rate of the silicon dioxide film was evaluated. The results are shown in FIGS. 7 and 8. FIGS. 7 and 8 show dependency of the etching rate of the polysilazane films (relative to the silicon dioxide film) obtained in the Examples 7 and 8 on the in-plane position of the wafer. FIG. 7 shows the results of investigation of the polysilazane film obtained from the solution prepared in the clean environment, while FIG. 8 shows the results of investigation of the polysilazane film obtained from the solution prepared in the contaminated environment. The VOC concentration in each environment is the same as in Example 4.

As shown in FIG. 7, the etching rate of the film containing the amine does not so largely differ from the etching rate of the film containing no amine when the sample is prepared in the clean environment, although the etching rate slightly decreases with the addition of the amine.

On the contrary, FIG. 8 shows that the etching rate decreases by adding only 5 ppm of the amine when the sample was prepared in the contaminated environment. This suggests that conversion of the polysilazane film into the silicon dioxide film was advanced by the catalytic function of the amine. It is also shown that the etching rate is largely distributed depending on the position of the polysilazane film when the amount of addition of the amine is 5 ppm or more. The etching rate is particularly slow at the center of the wafer, probably because of temperature distribution during the heat treatment process.

FIGS. 7 and 8 show that the catalytic effect of the amine is amplified in the contaminated environment. However, no differences in the etching rate and in in-plane distribution of the etching rate of the wafer are observed in the clean environment and contaminated environment when no amine is added. Accordingly, the lower the amine concentration is, the better.

The above-mentioned results of evaluation show an example of evaluation of the environment for preparing the polysilazane solution. However, the same holds true for any environments for handling polysilazane-base substances such as synthesis and chemical modification of polysilazane, filling of the polysilazane solution into a vessel, transfer of the solution from one vessel to another vessel and film-forming steps using the polysilazane solution.

The results of this example show that mingling of the amine adversely affects the polysilazane film, and that the environment for handling the polysilazane solution is also important. The lower the VOC concentration is, the better, in the handling environment. In particular, in the case where the polysilazane solution is prepared in the contaminated environment, the rate of change of the contraction rate of the polysilazane film is quite large when a trace amount of the amine is mingled as compared with the polysilazane film containing no amine. Accordingly, the lower the amine concentration is, the better.

### Example 8

The polysilazane film was evaluated through observation of peeling of the polysilazane film in Example 8. The polysilazane film after firing in Example 4 was used as the sample in Example 8.

Specifically, the sample formed by the following steps was observed. A SiN layer with a thickness of 150 nm was formed on the surface of the silicon wafer, the SiN layer and wafer were etched by a lithographic method, and trenches with a linear planar configuration and a depth of 300 nm were formed on the wafer. The width of the pattern on the surface of the wafer between the trenches was from 0.1 to 2 μm.

Then, the polysilazane film was applied on the entire surface of the wafer as in Example 4, and the polysilazane film was fired. As a result, the wafer was completely covered with the polysilazane film, which was also filled in the trench. Subsequently, an excess polysilazane film on the surface of the wafer was removed by a CMP (chemical mechanical polishing) method until the SiN layer was exposed. Then, the surface of the polysilazane film in the trench was made to retreat about 100 nm from the surface with hydrofluoric acid.

The sample prepared as described above was observed from the top surface with an electron microscope. The results are shown in FIG. 9. FIG. 9 shows peeling, if any, of the polysilazane film obtained in Example 8 of the invention. “Peeling” in the table means that the embedded polysilazane film was peeled from the side wall of the trench. The film may be conjectured to be peeled by excessive conversion of polysilazane into silicon dioxide due to a catalytic effect of the amine, and the resulting abnormal contraction of the film. Contraction of the polysilazane film permits the film to be detached from the side wall of the trench to form gaps between the side wall and the film, and the side face of the polysilazane film is retreated as a result of invasion of hydrofluoric acid into the gaps. Consequently, linear gaps are observed between the polysilazane film and the trench in the sample that causes “peeling” of the film.

FIG. 9 shows that “peeling” appears in the sample having the polysilazane film that has been prepared in the contaminated environment by adding 6-dimethylamino-1-hexanol.

The result of evaluation described above is an example of evaluation of the environment when the polysilazane solution is prepared. However, the same holds true for any environments for handling polysilazane-base substances such as synthesis and chemical modification of polysilazane, filling of the polysilazane solution into a vessel, transfer of the polysilazane solution from one vessel to another vessel, hermetic sealing of the polysilazane solution and film forming step using the polysilazane solution.

Example 8 also shows that the polysilazane film is adversely affected by mingling of the amine, and it was confirmed that the environment for handling the polysilazane solution is important. The lower the VOC concentration is, the better, in the handling environment. When the polysilazane solution is prepared in the contaminated environment, in particular, mingling of even a trace amount of the amine causes peeling of the film. Accordingly, it is preferable that the polysilazane solution is handled in the clean environment, or the amine concentration is almost 0 ppm. More preferably, both conditions are satisfied.

### Example 9

The polysilazane solution was evaluated by ¹H-NMR analysis in Example 9.

The polysilazane solutions used in Examples 1 to 8 were analyzed by ¹H-NMR. As a result, peaks assigned to N—CHₓ were detected in the solutions to which amines such as 6-dimethylamino-1-hexanol, 4-dimethylamino-1-butanol and 2-dimethylamino-1-ethanol were added. Peaks assigned to O—CHₓ were also detected, and the intensity of the peak was increased by increasing the amount of addition of the amine. This suggests that Si—O—C bonds were formed by the reaction between the alcoholic group of the amine and polysilazane.

In other words, avoiding reactive substances (for example, amines except ammonia) containing nitrogen atoms from mingling is necessary in the synthesis of the polysilazane resin, in the preparation of the sample and during the process for transferring the solution from one vessel to another vessel for obtaining good polysilazane solutions.

When PGMEA was added (Examples 2 and 3), peaks assigned to O—CH₂ that was presumed to be formed by bonding between the alcoholic group of PGMEA and polysilazane were detected.

While the action of the amine and synergic effect of the amine with other chemical substances have been described mainly on polysilazane, the same holds true for handling all the polysilazane polymer materials having the Si—N bond. Accordingly, general descriptions are as follows. It is preferable that amines or basic substances (except ammonia) having N—R(—R′)(—R″) bonds (N is not in the main chain of polysilazane) are contained in a proportion of 10 ppm or less (including 0 ppm) relative to polymer weight in the polymer solution having the Si—N bond.

While compounds in which N in the Si—N bond is substituted with 0 have been described above, the same description is valid for compounds having N—R(—R′)(—R″) bonds (N is not an atom in a base polymer of polysilazane) in the side chain, functional group or modification group of the polymer having the Si—N bond such as polysilazane with respect to substitution of N with O. In other words, the content of the amine or basic substance (except ammonia) having the N—R(—R′)(—R″) bond (N is not an atom in the base polymer of polysilazane) in the side chain, functional group or modification group of the polymer having the Si—N bond is preferably 10 ppm or less (including 0 ppm) relative to the weight of the polysilazane base polymer.

### Example 10

Example 10 relates to a configuration for maintaining a clean environment by eliminating contaminants.

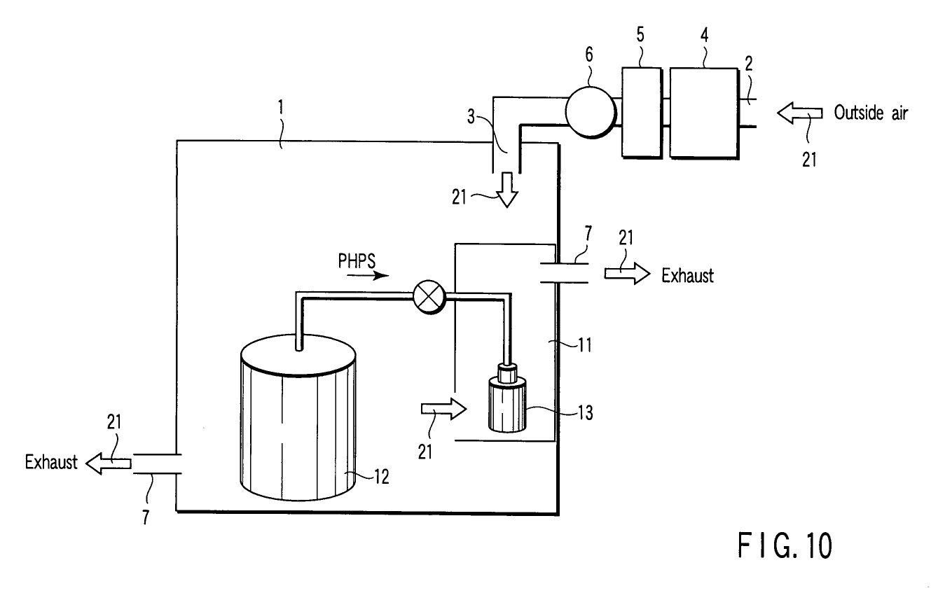

FIG. 10 shows an example of a system for forming a clean environment according to Example 10 of the invention. As shown in FIG. 10, outside air imported from an outside air inlet 2 is blown into a clean room 1 through an outside air exhaust port 3. An ammonia/VOC elimination filter (an adsorbent) 4 and a particle elimination filter 5 are provided between the outside air inlet 2 and exhaust port 3.

Outside air is blown into the clean room 1 through the ammonia/VOC elimination filter 4 and particle elimination filter 5. The pressure in the clean room 1 is controlled with a pump 6.

A filter provided in usual clean rooms may be used as the particle elimination filter 5. The ammonia/VOC elimination filter 4 has a function for eliminating substances that adversely affect the polysilazane solution as described in Examples 1 to 9, and is composed of a filter for adsorbing at least amines, basic substances, volatile organic compounds and acidic substances. Specific examples of the ammonia/VOC elimination filter 4 will be described later. An exhaust port 7 is provided in the clean room.

Since polysilazane or the polysilazane solution is used in a semiconductor production process, the chemicals are handled in a clean room environment from which particles have been eliminated. Substances that adversely affect polysilazane or polysilazane solution, and particles are eliminated from outside air by allowing the outside air to pass through the ammonia/VOC elimination filter 4 and particle elimination filter 5. The outside air from which these particles and substances have been removed is imported into the clean room 1. Air containing contaminating substances is prevented from invading into the clean room 1 through gaps of the clean room 1 by applying a positive pressure in the clean room 1 while the outside air from which contaminating substances and particles have been eliminated is imported into the clean room. The arrow 21 shows the flow of air.

A part of the air imported into the clean room 1 may be exhausted while the remaining air may be circulated for use. When the remaining air is circulated, it is important not to connect an air circulation pipeline to the upstream of the ammonia/VOC elimination filter 4. Since polysilazane reacts with moisture in air to generate ammonia while xylene or di-n-butylether is used as a solvent, the ammonia/VOC elimination filter 4 is deteriorated when the circulation pipeline is connected upstream of the filter. One end of the pipeline for circulating the remaining air is connected to the clean room 1, and the other end thereof is connected, for example, between the pump 6 and particle elimination filter 5.

Polysilazane uses an organic solvent, and generates ammonia. Accordingly, the polysilazane solution is preferably handled in a draft chamber that is isolated from the other areas in the clean room 1. Therefore, a working room (draft chamber) 11 is provided in the clean room 1. FIG. 10 shows an example for transferring the polysilazane solution from a large tank to a small vessel.

As shown in FIG. 10, a tank 12 that stores the polysilazane solution is disposed in the clean room 1. A bottle 13 for storing the polysilazane solution is placed in the draft chamber 11. The tank 12 is connected to the bottle 13 through a pipeline. A worker connects the pipeline from the tank 12 to the bottle 13 in the draft chamber 11, and transfers the polysilazane solution from the tank 12 to the bottle 13 by operating a valve or the like.

Air in the clean room 1 is directly sent to the draft chamber 11 through an opening for connecting the space in the clean room 1 to the space in the draft chamber 11. Accordingly, the particle elimination filter 5 as well as the ammonia/VOC elimination filter 4 are provided between the outside air inlet 2 and outside air exhaust port 3. This permits the entire space of the clean room 1 to be maintained in a clean environment while the inside of the draft chamber 11 is also maintained in a clean environment. The concept shown in FIG. 10 may be used for transferring the solution as well as in the steps for synthesizing the polysilazane resin and for preparing the polysilazane solution.

Various works such as preparation of the polysilazane solution, synthesis of the polysilazane resin and transfer of the solution are carried out in the clean room 1 into which air after passing through the ammonia/VOC elimination filter 4 is mainly supplied. The phrase “only air after passing through the filter 4 is substantially supplied” means that the clean room 1 is composed of a space substantially isolated from outside air (in the sense of excluding fine gaps), and the air feed passageway to the clean room 1 passes through the filter 4.

Substances generated by allowing the solvent of the polysilazane solution and polysilazane solution to react with substances (such as moisture) that are not removed by the ammonia/VOC elimination filter 4 are left behind in the clean room 1, even when air is supplied to the clean room 1 through the ammonia/VOC elimination filter 4.

The ammonia/VOC elimination filter 4 will be described below. Commercially available basic substance elimination filters, acidic substance elimination filters and organic substance elimination filters may be appropriately combined for use as the ammonia/VOC elimination filter 4.

An example of the commercially available filters for this purpose is ChemArrest (trade name, manufactured by Cambridge Filter Japan, Ltd.). Acid elimination, alkali elimination and organic substance elimination filters are available as this filter. These filters are able to eliminate the following substances according to the home page of Cambridge Filter Japan, Ltd.:

Acid elimination filter: sulfur dioxide (SO₂, SO₄²⁺), hydrogen disulfide (H₂S), hydrogen chloride (HCl), hydrogen fluoride (HF), nitrogen oxide (NO₂, NO₂⁻, NO₃⁻), formic acid (HCOOH), acetic acid (CH₃COOH), boron compounds (H₃BO₃, BF₃ and the like), nitrogen dioxide, phosphoric acid, acidic gas, methyl mercaptan and composite odor;

Alkali elimination filter: ammonia, trimethylamine, organic bases (such as NMP) and composite odor;

Organic substance elimination filter: solvents such as benzene, toluene, xylene and styrene, phthalic acid esters (such as DOP, DBP and DEP), phosphoric acid esters (such as TBP, TEP and TMP), fatty acid esters (such as ethyl stearate), cyclic siloxane (D3 to D11), phenolic antioxidants (such as BHA and BHT), organic bases (such as NMP), organic acids, other organic compounds such as alcohols and aldehydes, ozone, sulfur dioxide, methyl disulfide and composite odor.

The ammonia/VOC elimination filter 4 needs to be periodically replaced with a new filter. The timing of replacement may be determined by calculating the service life of the ammonia/VOC elimination filter 4 from the change of elimination efficiency of the filter. The elimination efficiency of contaminants may be calculated by periodically measuring the concentration of the contaminants, or may be estimated by measuring the concentration of the contaminants in the atmosphere in advance and referring to the time-dependent changes of the elimination efficiency of a standard substance (for example, toluene). The filter is desirably replaced before the elimination efficiency decreases to at least 90%.

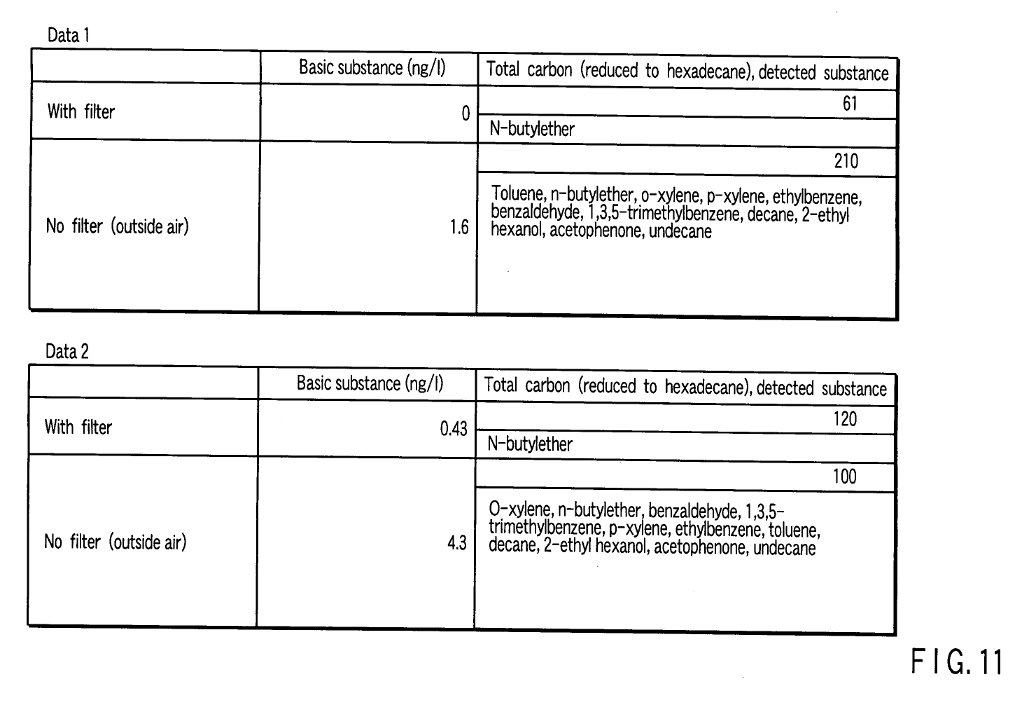

FIG. 11 shows the concentration of chemicals in the clean room 1 in the cases where the ammonia/VOC elimination filter 4 is attached and not attached according to Example 10. The concentration was measured twice, one each in one day and another day. Data 1 and data 2 correspond to the results of measurement in each day of measurement. The data were acquired using the filter manufactured by Cambridge Filter Japan, Ltd.

The measurement procedure was as follows. An air sample was collected in pure water by an impinger method, and the basic substance was measured by ion chromatography. The air sample was made to pass through the filter 4 (air in the clean room 1), or was not treated with the filter (outside air). It was confirmed from the results of measurements shown in FIG. 11 that basic substances except ammonia were not detected, and the concentration of ammonia in the clean room was suppressed to 1/10 or less of outside air. Ammonia observed in the clean room 1 is considered to be formed by auto-contamination of polysilazane (polysilazane generates ammonia gas by reacting with moisture in air).

Air collected with TENAX (trade name) collection tube was analyzed by GC-MS (gas chromatography-mass spectrometry), and the VOC concentration was calculated by reducing into the concentration of hexadecane. FIG. 11 describes the amount of total carbon as well as detected substances.

Various chemicals were contained in outside air, although they differ between the two measurements. Substances such as alcohols, aldehydes and ketones that are readily dissolved in the polysilazane solution and adversely affect the solution by reacting with polysilazane were contained in the chemicals. These substances may impair the polysilazane film as shown in Example 3 to 6 even when amines are not contained in the solution.

On the other hand, only di-n-butylether is detected in the clean room 1, and it was confirmed that contaminants that deteriorate the characteristics of the polysilazane film were completely eliminated. Since di-n-butylether is the solvent of the polysilazane solution, it is natural that the compound is generated in the clean room 1 and is detected irrespective of the presence or absence of the filter.

It is inevitable that the concentration of di-n-butylether increases as a result of works using the polysilazane solution in the clean room 1 for the same reason. Accordingly, the level of the total carbon that is dependent on the concentration of di-n-butylether is not always lower when the filter is used than the level when no filter is used. Rather, it is important that chemicals detected when no filter is used are not detected when the filter is used. In other words, it is important that contaminants in air imported into the clean room are eliminated.

The clean environment forming system according to Example 10 of the invention is provided with the ammonia/VOC elimination filter 4 at the outside air inlet 2 to the clean room 1. Accordingly, impurities (except ammonia and solvents generated from polysilazane or polysilazane solution) that may adversely affect polysilazane or polysilazane film including those shown in Examples 1 to 9 (including at least amines) are removed from air in the clean room 1. Consequently, polysilazane or polysilazane solution may be maintained in a state capable of being converted into a silica-base insulation film or a lower dielectric constant (low-k) film having good characteristics for making the film to be hardly peeled in the semiconductor device.

### Example 11

Example 11 relates to an automated processing apparatus for processing polysilazane or polysilazane solution under a condition in which the clean environment is maintained.

Substances that adversely affect polysilazane or polysilazane solution also originate in human body, and cosmetics are a representative of contamination sources. Accordingly, the processing apparatus of polysilazane or polysilazane solution is preferably isolated from workers.

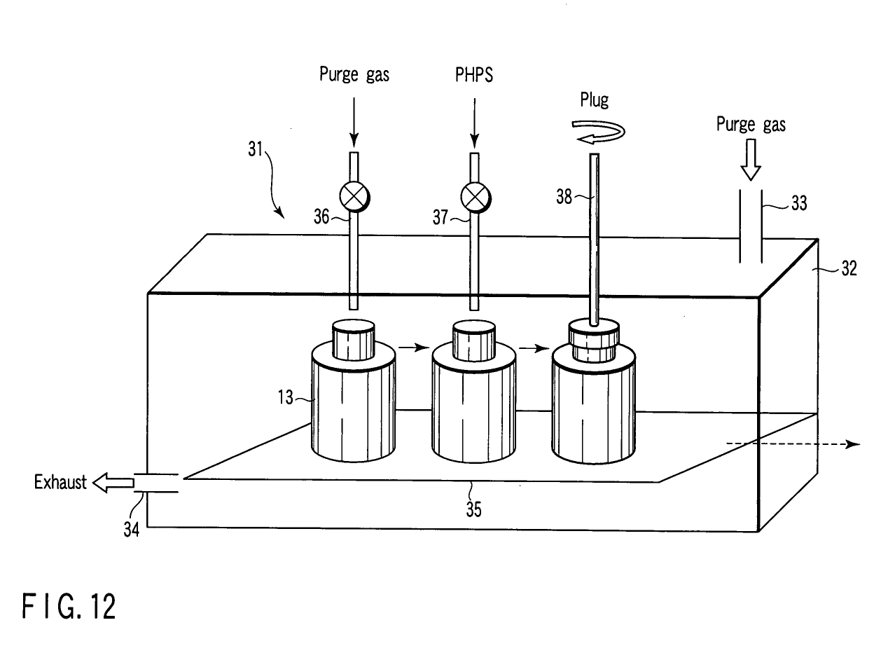

FIG. 12 shows a processing apparatus 31 according to Example 11 of the invention. FIG. 12 conceptually illustrates an example of an automation system for transferring the polysilazane solution from a large tank (not shown) to a small vessel. As shown in FIG. 12, the processing apparatus 31 provided in the clean room 1 has a processing chamber 32. An inert gas for purging, for example N₂ gas, is brown into the processing chamber 32 from a gas inlet 33, and the inside of the processing chamber 32 is filled with N₂ gas. An exhaust port 34 is also provided in the processing chamber 32.

The processing chamber 32 is shielded except an access port of a conveyer 35 so that no contaminants invade from the outside.

The conveyer 35 is provided in the processing chamber 32, and a bottle 13 for storing the solution is arranged on the conveyer 35. The processing chamber 32 is isolated from the worker, the bottle 13 moves in the processing chamber 32 according to a work flow, and the process is carried out at a predetermined position. The bottle 13 is carried into the processing chamber 32 by means of the conveyer 35 in the first step.

Then, the bottle 13 is set under a purge gas feed pipe 36 with the conveyer 35, and at this position, the inside of the bottle 13 is filled with the inert gas for purging, for example N₂ gas. Subsequently, the bottle 13 is placed under a polysilazane solution feed pipe 37 with the conveyer 35, and the polysilazane solution is supplied to the bottle 13 from the feed pipe 37 at this position.

Then, the bottle 13 is placed under a plugging apparatus 38 with the conveyor 35, and a plug is attached to the bottle 13 at this position to hermetically seal the bottle 13. The bottle 13 is carried out of the processing chamber 32 thereafter with the conveyer 35. A door that opens only when the bottle 13 is carried in and out of the processing chamber 32 may be provided around the conveyer 35.

In FIG. 12, the purge gas feed pipe 36 for purging the inside of the bottle 13 is different from the polysilazane solution feed pipe 37. However, it is possible to combine these pipes into one pipe so that the gas and solution are supplied one after another. This arrangement permits the size of the processing apparatus 31 to be reduced while the processing efficiency is improved since movement at the time of process, in particular movement of the bottle 13 with the conveyer 35, may be saved.

The gas for purging the insides of the processing chamber 32 and bottle 13 is not restricted to nitrogen, and any gases that do not adversely affect the polysilazane solution may be available.

The processing apparatus according to Example 11 may be provided in the clean room 1 in Example 10 (FIG. 10). Since the process is completed without entrance of the worker in the processing chamber 32, the processing apparatus 31 may be provided in a usual clean room having no ammonia/VOC elimination filter 4.

The concept as set forth herein may be applied not only to transfer of the polysilazane solution but also to the steps for synthesizing the polysilazane resin and for preparing the sample. It is necessary to automatically perform these processing steps in a processing chamber (such as processing chamber 32) isolated from the worker. Therefore, it is desirable that the processing chamber is isolated from the space where the worker is attending, and each step may be carried out in the processing chamber filled with a gas that does not adversely affect polysilazane.

According to the processing apparatus of Example 11 of the invention, the work using polysilazane or polysilazane solution may be automatically performed in the processing chamber 32 that is isolated from the worker and in which a gas that does not adversely affect polysilazane is filled. Accordingly, any substances that adversely affect polysilazane including those originating in the human body are prevented from mingling into the polysilazane solution. Consequently, the polysilazane solution may be obtained with little deterioration of various characteristics.

### Example 12

Example 12 relates to a processing apparatus for carrying out process using polysilazane under a condition that maintains a clean environment.

Polysilazane is used in the step for applying it on a semiconductor substrate in the step for producing the semiconductor device. A generally used coater having a rotary coating mechanism is used as the coating apparatus. One end of a tube for chemicals is attached to a bottle of the chemical, and the other end is connected to a nozzle of the chemical in a coater cup. The chemical is transferred to the nozzle from a bottle through a tube, and is ejected and applied on the semiconductor device by the nozzle.

The bottle of the chemical may be exchanged either in a hood provided in the coater, or on a station of chemicals provided outside the coater. Chemical substances that adversely affect polysilazane are desirably eliminated in any of these methods.

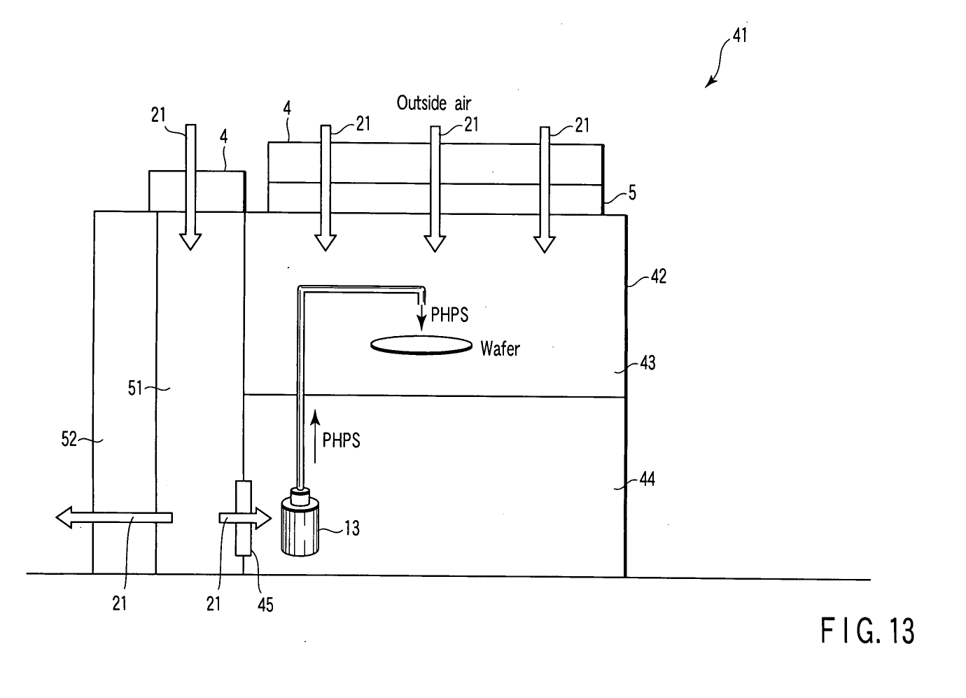

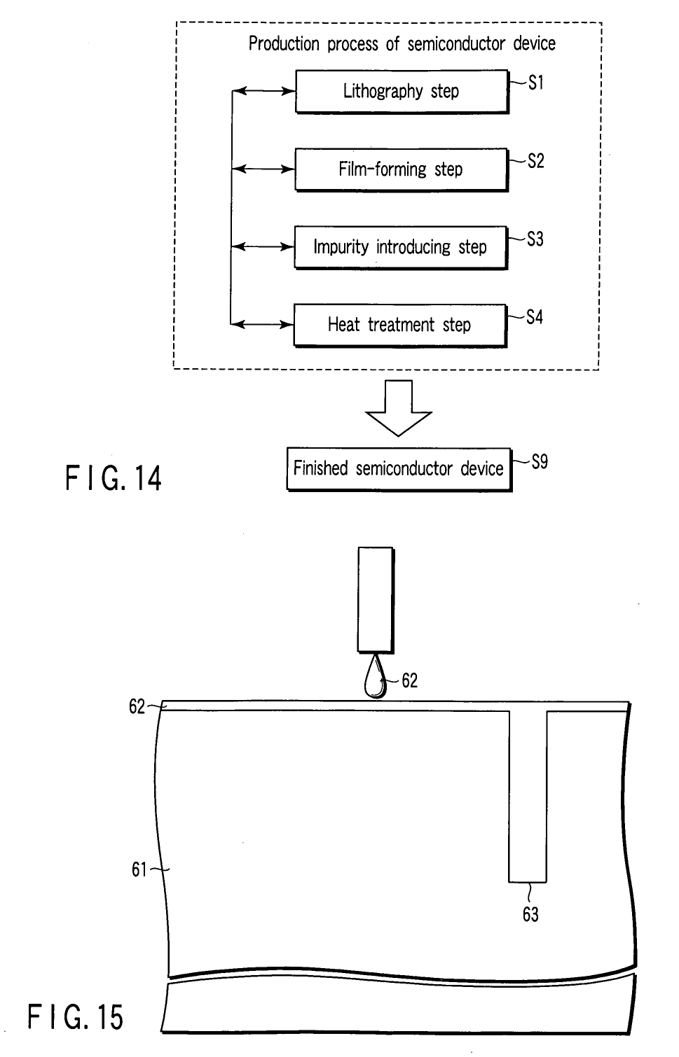

FIG. 13 shows a processing apparatus 41 according to Example 12 of the invention. As shown in FIG. 13, the processing apparatus 41 includes a coater body 42. The coater body 42 includes a processing chamber 43 in which the wafer is placed and the chemical is applied on the wafer, and a storage chamber 44 for storing a bottle 13 filled with the chemical. The processing chamber 43 and storage chamber 44 form spaces hermetically sealed from the outside. A door 45 is provided at the storage chamber 44. The bottle 13 placed in the storage chamber 44 is connected to the nozzle in the processing chamber 43 through a pipe for the chemical, which is ejected onto the wafer through the nozzle.

An ammonia/VOC elimination filter 4 and a particle elimination filter 5, which are connected in series, are provided on the ceiling of the processing chamber 43.

A hood 51 is provided at the side wall of the coater body 42. The hood 51 is a space having an appropriate size, and the worker is able to enter the hood 51 through a door 52 provided at the side wall of the hood 51. The hood 51 is also connected to the door 45 that leads to the processing chamber 44. The worker attends in the hood 51 for performing the work of exchanging the bottle 13. The ammonia/VOC elimination filter 4 is also provided on the ceiling of the hood.

The processing apparatus 41 is placed in the clean room. Otherwise, it may be placed in the clean room 1 according to Example 10. Air is brown into the processing chamber 43 through the ammonia/VOC elimination filter 4 and particle elimination filter 5.

On the other hand, air is brown into the hood 51 through the ammonia/VOC elimination filter 4. The inside of the hood 51 is kept to have a positive pressure. Accordingly, air in the hood 51 flows out of the hood 51 through the door 52 when the door 52 of the hood 51 is open. Air in the hood 51 also flows into the storage chamber 44 through the door 45 when the door of the storage chamber 44 is open. Since air in the hood 51 is introduced through the ammonia/VOC elimination filter 4, the polysilazane solution in the bottle 13 placed in the storage chamber 44 is prevented from coming into contact with contaminants. Since air also flows into the storage chamber 44 from the hood 51, the worker is protected from touching organic solvents to ensure safety of the worker during work.

According to the processing apparatus of Example 12 of the invention, the bottle 13 of the polysilazane solution is placed in the storage chamber 44 isolated from the outside, and the storage chamber 44 is in contact with the hood 51 filled with air introduced through the ammonia/VOC elimination filter 4 via the door 45. The polysilazane solution in the bottle 13 is prevented from coming into contact with the contaminants when the worker works in the hood 51. Accordingly, the polysilazane solution can be maintained with little deterioration of various characteristics.

(Method for Producing Semiconductor Device)

### Example 13

Example 13 relates to a method for producing a semiconductor device using the polysilazane solution obtained in Examples 10 to 12, or using the processing apparatus of the polysilazane solution, and more specifically to a method for forming the polysilazane film.

The process for producing the semiconductor device includes various processing steps. For example, various known steps for producing the semiconductor device such as a lithographic step (step S1), a film forming step (step S3), an impurity introducing step (step S2) and heat-treatment step (step S4) are applied at given stages a predetermined number of times. Finally, the semiconductor device is formed (step S9).

Among various film forming steps, the step for forming the polysilazane film is performed for filling trenches for STI, and for forming PMD films, IMD films and low-k films. Accordingly, the state of the semiconductor substrate during the step for forming the polysilazane film varies in a quite wide range including the kinds of conductive films and insulation films that have been formed. A process for filling the trenches for STI will be described below as an example.

As shown in FIG. 15, a polysilazane solution 62, which is in a clean environment and contains a given amount of amine according to the foregoing examples, is applied on the entire semiconductor substrate or underlying film 61 by a spin coating method. Trenches 63 formed in the semiconductor substrate or underlying film 61 are favorably filled with the polysilazane solution 62.

The solvent may be removed by evaporation by baking the substrate at 150° C. for 3 minutes on a hot plate. The thickness of the finished film may be changed in the range of 100 nm to 1 μm by adjusting the concentration of the solution and the rotation speed of the substrate. The thickness of the film is appropriately selected depending on the uses and processes.

The polysilazane film is converted into an insulation film by oxidation in an atmosphere containing water vapor. For example, the polysilazane film can be oxidized in the temperature range of 230° C. or more and 900° C. or less. The time for oxidation is preferably 5 minutes or more in terms of stabilizing the atmosphere and temperature in the steam furnace. However, excessive oxidation by prolonged reaction time should be avoided since oxidation may advance to the substrate. Accordingly, the upper limit of the oxidation time is desirably 60 minutes.

The silica-base insulation film can be denser by heat-treating in the temperature range of 700° C. or more and 1100° C. or less in an inert gas atmosphere. It is difficult to sufficiently densify the film at a temperature of less than 700° C. It is to be noted that the depth of diffusion of the channel layer that has been formed in advance by ion injection may be increased in some semiconductor devices when the temperature exceeds 1100° C. The heat treatment time may be appropriately selected in the range of 1 second to 120 minutes. Applying the heat treatment under these conditions permits water to be removed from the silicon dioxide film to enable dense film to be formed, and consequently electric characteristics of the semiconductor device can be improved.

According to the method for producing the semiconductor device in Example 13 of the invention, the insulation film is formed by using the polysilazane solution that contains contaminants in the range according to Examples 1 to 11 and has been handled in the handling environment as shown in Examples 1 to 11. Accordingly, an insulation film that is hardly peelable, has good characteristics and is suitable for the semiconductor device can be formed.

The method for forming the silicon dioxide film according to the invention may be applied to all the elements produced through lithographic steps such as a magnetic element, MEMS (micro electro mechanical systems) and DNA chip in addition to the semiconductor device.

(Method for Measuring Concentration)

The concentration of the contaminant in the polysilazane solution has been defined in ppm unit in the examples that have been described above. Another method for estimating the amount of the contaminant will be described below.

The amine used in the foregoing examples can be quantified by ¹H-NMR since the compound has an N—CH₂ bond. The peak assigned to this proton is observed at a chemical shift in the range of about 2 ppm to 4 ppm with reference to the peak of TMS (tetramethyl silane). Dimethylaminoethanol is selected as an amine having a small molecular weight, and the NMR peak intensity when this amine is contained by 10 ppm by weight relative to the polysilazane resin is calculated. While the proportion of the hydrogen atom in polysilazane has been known to be from 5 to 15 wt % (Japanese Patent Nos. 2670501 and 3015104), the proportion may be larger or smaller than this value since it is different depending on the production methods of the resin.

Assuming that the proportion of hydrogen is 5 wt % as a representative value, then a value of 4.5×10⁻⁶ is obtained as a ratio of the ¹H-NMR integrated intensity assigned to N—CH₂ (N is not an atom in the base polymer of polysilazane) to the integrated intensity assigned to total hydrogen of polysilazane. The integrated intensity is proportional to the number of the hydrogen atoms. The total number of the hydrogen atoms in polysilazane corresponds to the total number of the hydrogen atoms in SiHₓ (x is an integer from 1 to 3) and in NH_{y} (N is an atom in the polysilazane base polymer and y is an integer of 1 or 2).

The hydrogen content in polysilazane and the kind of the amine in concern may be changed depending on the conditions. Accordingly, a value of 1×10⁻⁵ or less is obtained by doubling the above-mentioned integrated intensity as a safety factor. Accordingly, a polysilazane solution with a number of the hydrogen atoms ascribed to the amine of 1×10⁻⁵ or less (including zero) is preferable as polysilazane containing 10 ppm or less of the amine, for forming insulation films. While N—CH₂ has been shown as an example, the results may be generalized for N—CH_{z} (z is an integer from 1 to 3).

The same results can be obtained for chemically modified polysilazane by defining the proportion of hydrogen in polysilazane before chemical modification, because hydrogen bonded to Si—N in polysilazane before chemical modification is exchanged by another substituent. Measurements of ²⁹Si-NMR and ¹³C-NMR are valid for estimating the amount of substituted hydrogen in polysilazane after chemical modification.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for handling polysilazane or a polysilazane solution comprising:
synthesizing polysilazane and preparing the polysilazane solution in a first space isolated from outside air, the first space being mainly supplied with air from which amine, basic substance, volatile organic compound and acidic substance are eliminated.

2. The method according to claim 1, wherein the air from which the amine, basic substance, volatile organic substance and acidic substance are eliminated is formed by allowing outside air to pass through an adsorbent which adsorbs the amine, basic substance, volatile organic substance and acidic substance.

3. The method according to claim 1, wherein handling the polysilazane or polysilazane solution including synthesis of the polysilazane and preparation of the polysilazane solution is performed in a second space provided in the first space and filled with an inert gas.

4. The method according to claim 1, wherein handling the polysilazane or polysilazane solution including synthesis of the polysilazane and preparation of the polysilazane solution includes feeding the polysilazane or polysilazane solution to a first vessel.

5. The method according to claim 4, wherein feeding the polysilazane or polysilazane solution to the first vessel includes transferring the polysilazane or polysilazane solution from a second vessel to the first vessel.

6. A polysilazane solution comprising:
an amine having an N—R(—R′)(—R″) bond or a basic substance except ammonia in a proportion of 10 ppm or less in a solution of a polymer having a Si—N bond relative to a weight of the polymer, or in a proportion of 10 ppm or less in a side chain, functional group or chemical modification group of a polymer having a Si—N bond relative to a weight of a polysilazane base polymer.

7. Polysilazane or a polysilazane solution, wherein a total number of hydrogen in an N—CH_{Z} bond (N is not an atom in a polysilazane base polymer, and z is an integer from 1 to 3) contained in the polysilazane or in the polysilazane solution is 1×10⁻⁵ or less of a sum of the total number of hydrogen in SiAₓ (A represents hydrogen or a substituent substituting hydrogen, and x is an integer from 1 to 3) and NB_{y} (N is an atom in the polysilazane base polymer, B represents hydrogen or a substituent substituting hydrogen (including the same substituent as A), and y is an integer of 1 or 2) and the number of substituents substituted with hydrogen.

8. A method for producing a semiconductor device comprising:
forming a polysilazane film by applying polysilazane or a polysilazane solution on a semiconductor substrate, the polysilazane or polysilazane solution being obtained by the method according to claim 1.

9. The method according to claim 8, wherein the polysilazane film is used as an element isolation film or an interlayer insulation film.

10. The method according to claim 9, wherein the element isolation film is an element isolation film of memory cells.

11. A method for producing a semiconductor device comprising:
forming a polysilazane film by applying the polysilazane or the polysilazane solution according to claim 7 on a semiconductor substrate.

12. The method according to claim 11, wherein the polysilazane film is used as an element isolation film or an interlayer insulation film.

13. The method according to claim 12, wherein the element isolation film is an element isolation film of memory cells.
